(19) United States
(12) Patent Application Publication
(10) Pub. No.: US 2023/0063838 A1
(43) Pub. Date: Mar. 2, 2023

(54) LIGHT-RECEIVING CELL AND OPTICAL BIOMETRICS SENSOR USING THE SAME

(71) Applicant: EGIS TECHNOLOGY INC., Hsinchu City (TW)

(72) Inventors: BRUCE C. S. CHOU, Hsinchu City (TW); CHENCHANG HUANG, Hsinchu City (TW); CHEN-CHIH FAN, Hsinchu City (TW)

(21) Appl. No.: 17/792,036

(22) PCT Filed: Aug. 12, 2021
(86) PCT No.: PCT/CN2020/108600

§ 371 Date: Jul. 11, 2022

Related U.S. Application Data
(60) Provisional application No. 62/978,950, filed on Feb. 20, 2020.

(51) Int. Cl. G06V 40/13; H01L 27/146; G06V 10/147

(52) U.S. Cl. CPC G06V 40/1318; H01L 27/14623; H01L 27/14627; H01L 27/14678; G06V 10/147

(57) ABSTRACT

A light-receiving cell and an optical biometrics sensor using the same are provided. The light-receiving cell for converting optical energy into electrical energy includes: one or multiple main light-receiving regions; and a connection region directly connected to the one or multiple main light-receiving regions to form an area-reduced light-receiving region, wherein the light-receiving region has one or multiple area reduced parts to decrease junction capacitance and increase a sensing voltage signal.

### CROSS-REFERENCE TO RELATED APPLICATIONS

This application is a 371 of PCT/CN2020/108600 filed on Aug. 12, 2020, for which priority is claimed under 35 U.S.C. § 120, which claims priority of U.S. Provisional Application No. 62/978,950 filed on Feb. 20, 2020 under 35 U.S.C. § 119(e), the entire contents of all of which are hereby incorporated by reference.

### BACKGROUND OF THE INVENTION

### Field of the Invention

This disclosure relates to a light-receiving cell and an optical biometrics sensor using the same, and more particularly to a light-receiving cell and an optical biometrics sensor using the same, wherein an area of the light-receiving cell is reduced based on a light-receiving structure to decrease junction capacitance and increase a sensing voltage signal.

### Description of the Related Art

Today's mobile electronic devices (e.g., mobile phones, tablet computers, notebook computers and the like) are usually equipped with user biometrics recognition systems including different techniques relating to, for example, fingerprint, face, iris and the like, to protect security of personal data. Portable devices applied to mobile phones, smart watches and the like also have the mobile payment function, which further becomes a standard function for the user's biometrics recognition. The portable device, such as the mobile phone and the like, is further developed toward the full-display (or super-narrow border) trend, so that conventional capacitive fingerprint buttons can no longer be used, and new minimized optical imaging devices, some of which are very similar to the conventional camera module having complementary metal-oxide semiconductor (CMOS) image sensor (referred to as CIS) sensing members and an optical lens module, are thus evolved. The minimized optical imaging device is disposed under the display as an under-display device. The image of the object (more particularly the fingerprint) placed above the display can be captured through the partial light-transmitting display (more particularly the organic light emitting diode (OLED) display), and this can be called as fingerprint on display (FOD).

Conventional photosensors are usually formed on a semiconductor substrate (e.g., silicon (Si) substrate). However, a thin-film transistor (TFT) optical sensor manufactured using a glass material or an insulation material as a substrate becomes very important due to the price problem and the large-sensing area requirement (e.g., two fingers need to be sensed concurrently).

In order to increase the sensing voltage signal in the TFT optical fingerprint sensor, a light-receiving area of the light-receiving cell can be increased. However, when the area of the light-receiving cell is increased, the junction capacitance of the sensing member is also proportionally increased. Therefore, using the active pixel sensing cannot effectively increase the output voltage signal. So, how to increase the sensing voltage signal effectively is indeed a problem to be solved by this disclosure.

### BRIEF SUMMARY OF THE INVENTION

It is therefore an objective of this disclosure to provide a light-receiving cell and an optical biometrics sensor using the same, wherein an area of the light-receiving cell is reduced based on a light-receiving structure to decrease junction capacitance and increase a sensing voltage signal.

To achieve the above-identified object, this disclosure provides a light-receiving cell for converting optical energy into electrical energy. The light-receiving cell includes: one or multiple main light-receiving regions; and a connection region directly connected to the one or multiple main light-receiving regions to form an area-reduced light-receiving region having one or multiple area reduced parts to decrease junction capacitance and increase a sensing voltage signal.

In addition, this disclosure al so provides an optical biometrics sensor including: a sensing substrate having light-receiving cells; and a light transferring layer having light-receiving structures and being disposed on or above the sensing substrate, wherein the light-receiving structures respectively transfer light, coming from an object, to the light-receiving cells, each of the light-receiving structures includes an aperture, and each of the light-receiving cells includes: one or multiple main light-receiving regions receiving the light through multiple ones of the apertures; and a connection region directly connected to the one or multiple main light-receiving regions to form an area-reduced light-receiving region having one or multiple area reduced parts to decrease junction capacitance and increase a sensing voltage signal.

With the light-receiving cell and the optical biometrics sensor using the same according to the embodiments, the light-receiving range of the aperture depends on the collimating property of the collimator of the light-receiving structure or the light focusing property of the micro lens. So, the area of the light-receiving cell is reduced based on the light-receiving structure without affecting the light-receiving area of the light-receiving cell and without an extra process being added. The external shape of the light-receiving cell is modified according to the light-receiving structure to decrease junction capacitance and increase the sensing voltage signal.

In order to make the above-mentioned content of this disclosure more obvious and be easily understood, preferred embodiments will be described in detail as follows in conjunction with the accompanying drawings.

### BRIEF DESCRIPTION OF THE SEVERAL VIEWS OF THE DRAWINGS

FIGS. 1A and 1B are schematically partial cross-sectional views showing two examples of an optical biometrics sensor according to a preferred embodiment of this disclosure.

FIG. 2A is a pictorial view showing a sensing substrate and apertures formed thereon.

FIG. 2B is a schematic view showing a light-receiving cell.

FIG. 2C shows a sensing circuit diagram of the light-receiving cell.

FIG. 3 is a top view showing a preliminary embodiment of a light-receiving cell.

FIGS. 4 to 6 are top views showing three examples of light-receiving cells according to the preferred embodiment.

FIGS. 7A and 7B are schematic views showing two modified examples of the light-receiving cells of FIG. 5.

FIGS. 8 and 9 are schematic views showing two examples of an optical biometrics sensor applied to displays.

### SYMBOLS

A: area
AMP, RESET, READ: transistor
ARP: area reduced part
D1: diameter
F: object
W: distance
W1: width
VG, VPD, VDD: voltage
VSIG: voltage signal
10: sensing substrate
13: glass substrate
15: semiconductor substrate
20: light transferring layer
21: support layer
22: light shielding layer
23: optical layer
30: light-receiving structure
31: aperture
32: micro lens
50: display
51, 52: light-transmitting substrate
90: light-receiving cell
91: main light-receiving region
92: connection region
93: light-receiving region
94: transversal zone
95: longitudinal zone
96: section
97: first electrode plate
98: second electrode plate
99: dielectric
100, 100′: optical biometrics sensor

### DETAILED DESCRIPTION OF THE INVENTION

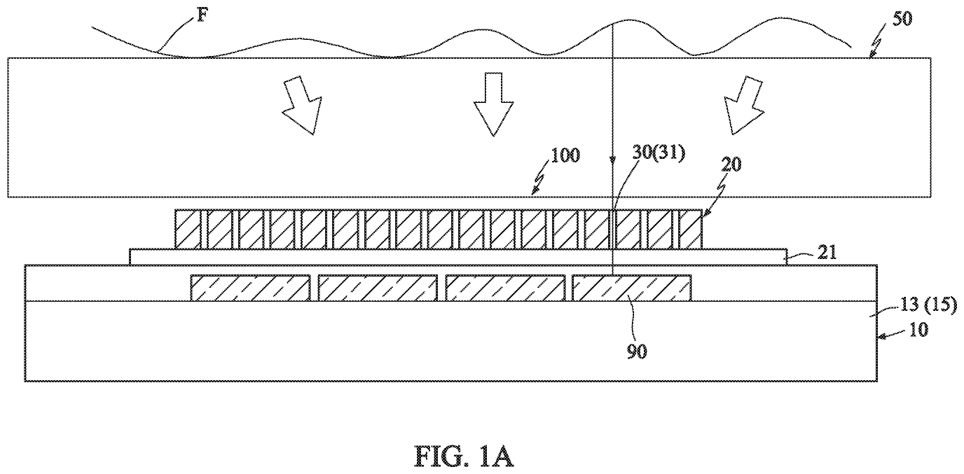

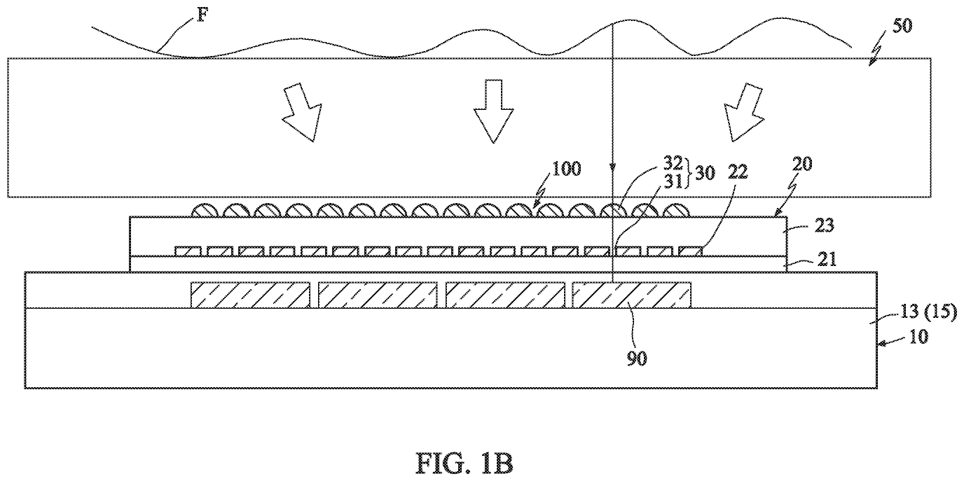

FIGS. 1A and 1B are schematically partial cross-sectional views showing two examples of an optical biometrics sensor 100 according to a preferred embodiment of this disclosure. Referring to FIGS. 1A and 1B, the optical biometrics sensor 100 of this embodiment includes a sensing substrate 10 and a light transferring layer 20.

The sensing substrate 10 having light-receiving cells 90 includes a glass substrate 13 or another insulation substrate. The light-receiving cells 90 are formed on the glass substrate 13. Alternatively, the sensing substrate 10 includes a semiconductor substrate 15, on which the light-receiving cells 90 are formed.

The light transferring layer 20 having light-receiving structures 30 is disposed on or above the sensing substrate 10 by way of bonding or attaching, or may be directly on or above the sensing substrate 10 by semiconductor processes. The light-receiving structures 30 respectively transfer light, coming from an object F disposed on or above a display 50, to the light-receiving cells 90. Each light-receiving structure 30 includes an aperture 31. Although the optical biometrics sensor 100 is explained by taking a fingerprint sensor, disposed under the display 50, as an example, this disclosure is not restricted thereto because the optical biometrics sensor 100 may also sense biometrics characteristics of the finger, such as the vein image, blood oxygen concentration image and the like, or biometrics characteristics of the face, iris and the like.

In FIG. 1A, each light-receiving structure 30 is an optical collimator without a micro lens and includes the aperture 31. In FIG. 1B, the light transferring layer 20 includes apertures 31 and micro lenses 32. That is, each light-receiving structure 30 further includes micro lenses 32 disposed above the apertures 31, and the light-receiving cells 90 sense the light, which is focused by the micro lenses 32 and passes through the apertures 31, respectively. On the other hand, the light transferring layer 20 includes a support layer 21, a light shielding layer 22 and an optical layer 23. The light shielding layer 22 disposed on the support layer 21 has the apertures 31. The optical layer 23 disposed on the light shielding layer 22 may have a filter structure for performing light filtering, such as filtering out the sunlight having the specific wavelength, or only allowing the infrared light to pass. The micro lenses 32 are disposed on the optical layer 23. The support layer 21 may be an adhesive layer, an insulating layer and the like. Two optical collimators provided in FIGS. 1A and 1B may be used to achieve the optical imaging objective in conjunction with the light-receiving cells 90.

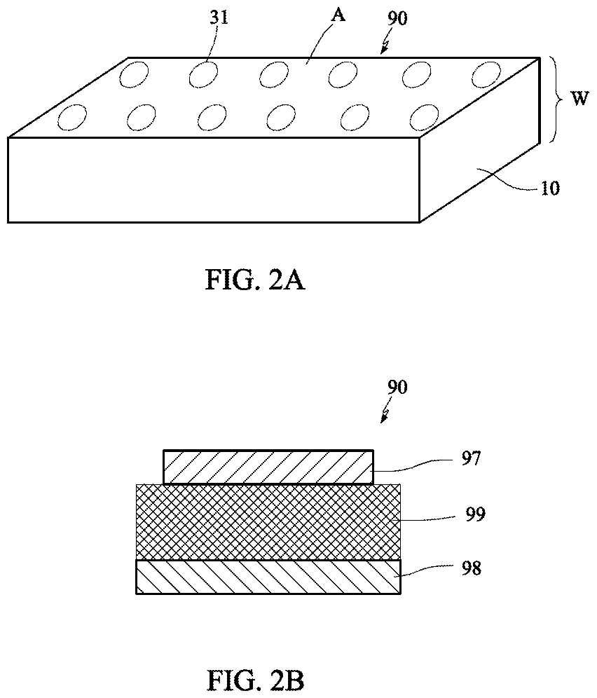

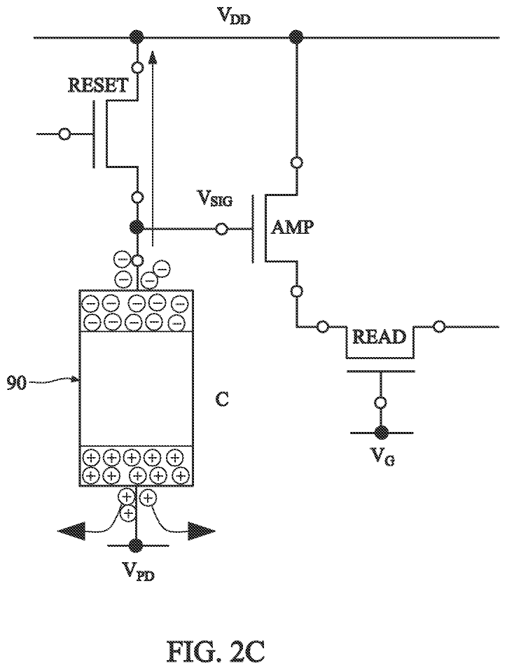

FIG. 2A is a pictorial view showing the sensing substrate 10 and the apertures 31 formed thereon. FIG. 2B is a schematic view showing a light-receiving cell. Referring to FIGS. 2A and 2B, the light-receiving cell 90 is implemented by a photo diode in this embodiment. In order to make the light-receiving cell 90 obtain the maximum incident light, an area A of the light-receiving cell 90 is enlarged according to the pixel size, so that the area A can correspond to the most apertures 31 (collimation holes) to obtain the maximum incident light energy. Although the enlarged area of the light-receiving cell 90 can increase the light input amount, the junction capacitance C thereof is also directly proportionally increased with the increase of the area A, wherein C=ε×(A/W), where ε is the dielectric constant of the dielectric 99 between a first electrode plate 97 and a second electrode plate 98, and W is the distance between the first electrode plate 97 and the second electrode plate 98. FIG. 2C shows a sensing circuit diagram of the light-receiving cell, which is the most commonly used pixel circuit architecture when the sensing substrate 10 is made of the glass or insulation material. As shown in FIG. 2C using the 3 transistor-active pixel sensor (3T-APS) architecture, three transistors RESET, AMP and READ are used and connected to the voltages VG, VPD, and VDD as shown in the drawing. The light-receiving cell 90, such as the photo diode, is illuminated to generate photo-electrons, which are accumulated on the junction capacitor of the photo diode and converted into the voltage signal. For the voltage signal V_{SIG} at the node of the transistor AMP, V_{SIG}=(Q_{light}/C) is given, where Q_{light} represents the number of photo-electrons directly proportionally to the light-receiving area A of the light-receiving cell 90, and C represents the junction capacitance of the pixel directly proportionally to the area A of the light-receiving cell 90. Therefore, simply enlarging the area A of the light-receiving cell 90 cannot effectively increase V_{SIG} according to the expression V_{SIG}=(Q_{light}/C).

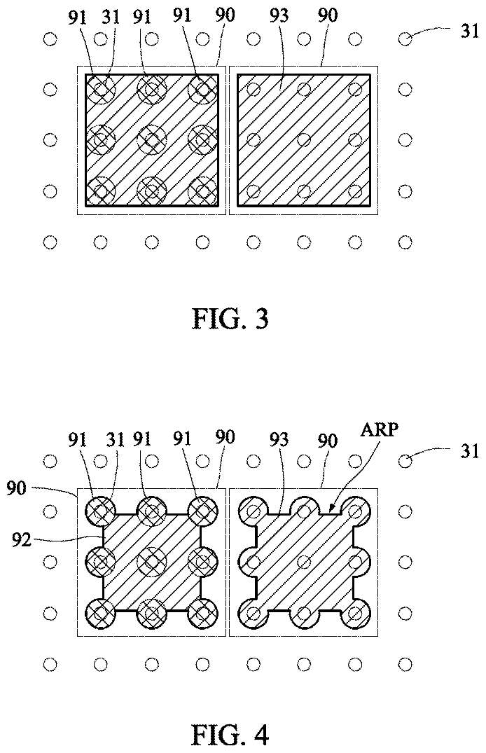

FIG. 3 is a top view showing a preliminary embodiment of a light-receiving cell. In order to solve the above-mentioned problems, the range of the light-receiving area, which should be originally extended to the overall light-receiving cell 90, is reduced into an area-reduced light-receiving region 93. This is because that the light-receiving range of each light-receiving cell 90 corresponding to the apertures 31 has a main light-receiving region 91, and that the area outside the main light-receiving region 91 receives no light, or only receives a very small amount of light. If the light-receiving area covers the overall light-receiving cell 90, then the advantage of increasing the light input amount cannot be obtained. On the contrary, the junction capacitance is disadvantageously increased and the sensing voltage signal is disadvantageously decreased. Therefore, the junction capacitance is decreased by cutting off the distribution area of the light-receiving cell 90, which is not disposed under the aperture 31 and cannot receive the light under the precondition without affecting the light input amount

FIGS. 4 to 6 are top views showing three examples of light-receiving cells according to the preferred embodiment, wherein the two light-receiving cells 90 on the left and right sides have the same structure, but have differently marked features. As shown in FIG. 4, the light-receiving cell 90 of this disclosure can be further improved so that each light-receiving cell 90 includes main light-receiving regions 91 and a connection region 92 based on the discovery from the embodiment of FIG. 3. The main light-receiving regions 91 receive the light through multiple ones of the apertures 31. Each main light-receiving region 91 has a circular shape. For example, nine main light-receiving regions 91 in FIG. 4 are arranged in a 3×3 array, and receive the light through nine apertures 31. The connection region 92 directly connects the main light-receiving regions 91 together to form an area-reduced light-receiving region 93 having one or multiple area reduced parts ARP. For example, the part ARP may have one or multiple concave contours, one or multiple concave corners or one or multiple truncated portions to decrease the junction capacitance of the light-receiving cell 90 and increase the sensing voltage signal. In this embodiment, the connection region 92 does not receive the light through the apertures 31. That is, the connection region 92 cannot receive any light passing through the apertures 31. Although nine main light-receiving regions 91 arranged in the 3×3 array are explained as an example, this disclosure is not restricted thereto. The main light-receiving regions 91 may also be arranged in a 2×2 array, a 4×4, a 5×5 square array and the like, and may also be arranged in a rectangular array. That is, the main light-receiving regions 91 are arranged in an M×N array, where M and N are positive integers greater than or equal to 1. In this case, the size or dimension of the light-receiving cell 90 is determined according to the size of one pixel of the sensor and the light-receiving range of the aperture(s). It is worth noting that partial areas of the light-receiving region 93 may also be hollowed out without affecting the light-receiving amount. Alternatively, one single main light-receiving region may be used in conjunction with one single connection region to form the light-receiving cell (having a radial shape in one example) according to different definitions or configurations. Therefore, the light-receiving cell may have one or multiple main light-receiving regions and one connection region directly connected to the one or multiple main light-receiving regions. In this case, one or multiple main light-receiving regions receive the light through one or multiple ones of the apertures.

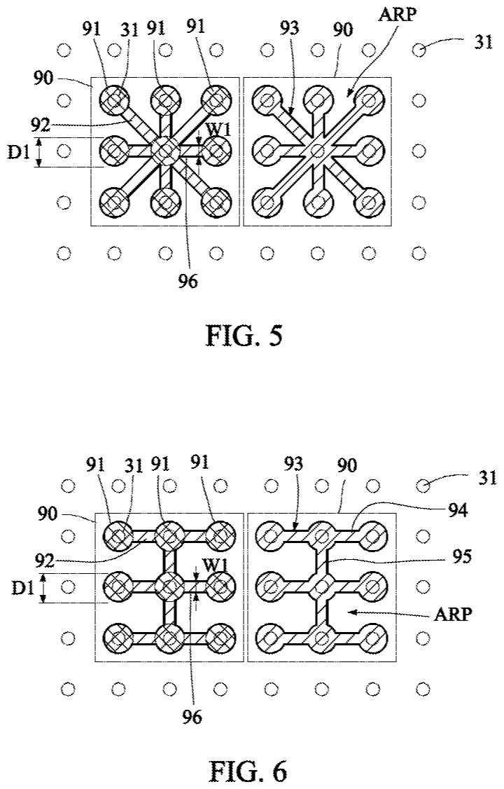

The example of FIG. 5 is similar to that of FIG. 4 except for the difference that the area-reduced light-receiving region 93 has a radial shape to further decrease the junction capacitance. The example of FIG. 6 is similar to that of FIG. 4 except for the difference that the area-reduced light-receiving region 93 has an intersecting pattern formed by multiple transversal zones 94 and one longitudinal zone 95 intersecting the transversal zones 94. The longitudinal zone 95 is perpendicular to or substantially perpendicular to the transversal zone 94 to further decrease the junction capacitance. In FIGS. 5 and 6, a width W1 of a section 96 of the connection region 92 connected to adjacent two of the main light-receiving regions 91 is smaller than a diameter D1 of the main light-receiving region 91. It is worth noting that the radial structure formed by the main light-receiving regions 91 and the connection region 92 in each light-receiving cell 90 may be one or both of the first electrode plate 97 and the second electrode plate 98 of FIG. 2B. When the first electrode plate 97 and the second electrode plate 98 have the same radial structure, one mask may be used to form both of them. When the first electrode plate 97 has the radial structure, the second electrode plate 98 may have the structure without the area-reduced parts (having the shape, such as the rectangular shape, different from that of the first electrode plate 97) and may be formed by the existing processes. Alternatively, the second electrode plate 98 may be configured to have the radial structure, while the first electrode plate 97 may be configured to have the structure without the area-reduced parts.

The optical biometrics sensor 100 may be an independent TFT sensor, or a CMOS sensor. In one example, the optical biometrics sensor may be an in-cell optical biometrics sensor in a TFT liquid crystal display (LCD) or a TFT OLED display.

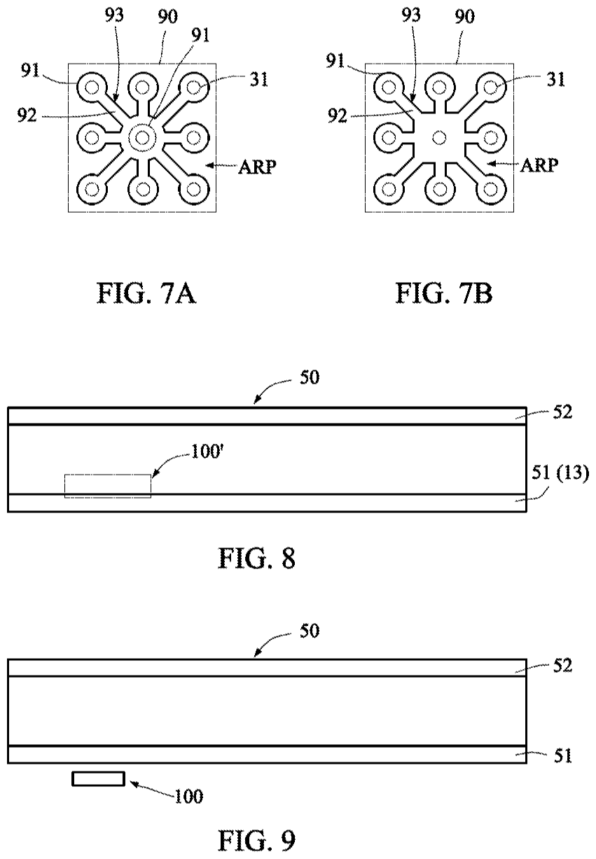

FIGS. 7A and 7B are schematic views showing two modified examples of the light-receiving cells of FIG. 5. Referring to FIG. 7A, the center zone of the connection region 92 has a circular shape, so that some acute-angle structures may be eliminated from the connection region 92 to simplify the manufacturing process and stabilize the structure of the connection region 92. Referring to FIG. 7B, the center zone of the connection region 92 has a rectangular shape, so that some acute-angle structures may be eliminated from the connection region 92 to simplify the manufacturing process and stabilize the structure of the connection region 92.

Referring to FIG. 8, an optical biometrics sensor 100′, which is similar to the optical biometrics sensor 100 and interspersed and integrated with display pixels (not shown), may be applied to the OLED display, the LCD or any other display having the TFT sensor formed by the TFT process, so that an in-cell sensor is provided. Therefore, the glass substrate 13 is one of two opposite light-transmitting substrates 51 and 52 of the display 50, and is the lower light-transmitting substrate 51 in FIG. 8. That is, the glass substrate 13 is one part of the light-transmitting substrate 51. The material layers between the two light-transmitting substrates 51 and 52 may be those present in the OLED display or the LCD. Although the optical biometrics sensor 100′ occupying a partial range of the display in FIG. 8 is explained as an example, this disclosure is not restricted thereto. The optical biometrics sensor 100′ may also extend to cover the full range of the display 50 and a full-display optical biometrics sensor is obtained. Referring to FIG. 9, the optical biometrics sensor 100 is an independent sensor, which may be a TFT or CMOS sensor disposed under the light-transmitting substrate 51.

This disclosure also provides a light-receiving cell 90 for converting optical energy into electrical energy. The light-receiving cell 90 includes main light-receiving regions 91 and a connection region 92, as mentioned hereinabove. The structure of the light-receiving cell 90 designed according to the above-mentioned requirements is also different from the conventional structure, and thus has the above-mentioned advantages.

With the light-receiving cell and the optical biometrics sensor using the same according to the embodiments, the light-receiving range of the aperture depends on the collimating property of the collimator of the light-receiving structure or the light focusing property of the micro lens. So, the area of the light-receiving cell is reduced based on the light-receiving structure without affecting the light-receiving area of the light-receiving cell and without an extra process being added. The external shape of the light-receiving cell is modified according to the light-receiving structure to decrease junction capacitance and increase the sensing voltage signal. Of course, although the structure and spirit of the embodiment are described in the form of the radial configuration in this disclosure, this disclosure does not intend to restrict the shape and structure thereto. Any configuration capable of achieving the objective of this disclosure by reducing the area of the junction capacitance is deemed as being covered by the spirit of this disclosure.

The specific embodiments proposed in the detailed description of this disclosure are only used to facilitate the description of the technical contents of this disclosure, and do not narrowly limit this disclosure to the above-mentioned embodiments. Various changes of implementations made without departing from the spirit of this disclosure and the scope of the claims are deemed as falling within the following claims.

What is claimed:

1. A light-receiving cell for converting optical energy into electrical energy, the light-receiving cell comprising:
one or multiple main light-receiving regions; and
a connection region directly connected to the one or multiple main light-receiving regions to form an area-reduced light-receiving region having one or multiple area reduced parts to decrease junction capacitance and increase a sensing voltage signal.

2. The light-receiving cell according to claim 1, wherein each of the main light-receiving regions has a circular shape.

3. The light-receiving cell according to claim 1, wherein the main light-receiving regions are arranged in an M×N array, where M and N are positive integers greater than or equal to 1.

4. The light-receiving cell according to claim 1, wherein a first electrode plate of the light-receiving cell has the area-reduced light-receiving region, and a second electrode plate of the light-receiving cell has a shape different from a shape of the first electrode plate.

5. The light-receiving cell according to claim 1, wherein the area-reduced light-receiving region has an intersecting pattern formed by transversal zones and a longitudinal zone.

6. The light-receiving cell according to claim 1, wherein a section of the connection region connected to adjacent two of the main light-receiving regions has a width smaller than a diameter of the main light-receiving region.

7. An optical biometrics sensor, comprising:
a sensing substrate having light-receiving cells; and
a light transferring layer having light-receiving structures and being disposed on or above the sensing substrate, wherein the light-receiving structures respectively transfer light, coming from an object, to the light-receiving cells, each of the light-receiving structures comprises an aperture, and each of the light-receiving cells comprises:
one or multiple main light-receiving regions receiving the light through one or multiple ones of the apertures; and
a connection region directly connected to the one or multiple main light-receiving regions to form an area-reduced light-receiving region having one or multiple area reduced parts (ARP) to decrease junction capacitance and increase a sensing voltage signal.

8. The optical biometrics sensor according to claim 7, wherein the connection region does not receive the light through the apertures.

9. The optical biometrics sensor according to claim 7, wherein each of the main light-receiving regions has a circular shape.

10. The optical biometrics sensor according to claim 7, wherein the main light-receiving regions are arranged in an M×N array, where M and N are positive integers greater than or equal to 1.

11. The optical biometrics sensor according to claim 7, wherein a first electrode plate of the light-receiving cell has the area-reduced light-receiving region, and a second electrode plate of the light-receiving cell has a shape different from a shape of the first electrode plate.

12. The optical biometrics sensor according to claim 7, wherein the area-reduced light-receiving region has an intersecting pattern formed by transversal zones and a longitudinal zone.

13. The optical biometrics sensor according to claim 7, wherein a section of the connection region connected to adjacent two of the main light-receiving regions has a width smaller than a diameter of the main light-receiving region.

14. The optical biometrics sensor according to claim 7, wherein each of the light-receiving structures further comprises a micro lens disposed above the aperture, and the light-receiving cells sense the light, which is focused by the micro lenses (32) and passes through the apertures, respectively.

15. The optical biometrics sensor according to claim 14, wherein the light transferring layer comprises: a support layer; a light shielding layer being disposed on the support layer and having the apertures; and an optical layer disposed on the light shielding layer, wherein the micro lenses are disposed on the optical layer.

16. The optical biometrics sensor according to claim 7, wherein each of the light-receiving structures is an optical collimator without a micro lens.

17. The optical biometrics sensor according to claim 7, wherein the sensing substrate comprises a glass substrate, on which the light-receiving cells are formed.

18. The optical biometrics sensor according to claim 17, wherein the glass substrate is one of two opposite light-transmitting substrates of a display.

19. The optical biometrics sensor according to claim 7, wherein the sensing substrate comprises a semiconductor substrate, on which the light-receiving cells are formed.
